(19) United States
(12) Patent Application Publication
(10) Pub. No.: US 2025/0379046 A1
(43) Pub. Date: Dec. 11, 2025

(54) SUBSTRATE TREATING APPARATUS

(71) Applicant: SEMES CO., LTD., Cheonan-si (KR)

(72) Inventors: Hyung Gyu KIM, Ansan-si (KR); Seung Hoon OH, Cheonan-si (KR); Eun Seok KIM, Asan-si (KR); Hye Bin GWON, Cheonan-si (KR)

(73) Assignee: SEMES CO., LTD., Cheonan-si (KR)

(21) Appl. No.: 19/232,111

(22) Filed: Jun. 9, 2025

(30) Foreign Application Priority Data
Jun. 10, 2024 (KR) 10-2024-0074804

(51) Int. Cl. H01L 21/02; H01L 21/67

(52) U.S. Cl. CPC H01L 21/02101; H01L 21/67034; H01L 21/67248

(57) ABSTRACT

The present invention relates to an apparatus for treating a substrate, and more particularly, to an apparatus for dry-treating a substrate by using a supercritical fluid. The apparatus for treating a substrate includes: a vessel having a treatment space; a support unit for supporting a substrate in the treatment space; a fluid supply unit for supplying a treatment fluid to the treatment space; a fluid exhaust unit for exhausting the treatment fluid from the treatment space; a heating unit installed in the vessel to heat the treatment space; and a temperature measurement unit installed in the vessel to measure the temperature of the treatment space, in which the vessel includes: a housing providing the treatment space; and a cover unit for covering a part or an entirety of an inner wall of the housing exposed to the treatment space in the inner wall of the housing, and the temperature measurement unit includes a temperature sensor provided between the housing and the cover unit.

### CROSS-REFERENCE TO RELATED APPLICATIONS

This application claims priority to and the benefit of Korean Patent Application No. 10-2024-0074804 filed in the Korean Intellectual Prope Office on Jun. 10, 2024, the entire contents of which are incorporated herein by reference.

### TECHNICAL FIELD

The present invention relates to an apparatus for treating a substrate, and more particularly, to an apparatus for dry-treating a substrate by using a supercritical fluid.

### BACKGROUND ART

In order to manufacture a semiconductor device, a desired pattern is formed on a substrate, such as a wafer, through various processes, such as photography, etching, ashing, ion implantation, and thin film deposition. Various treatment liquids and treatment gas are used in each process, and particles and process by-products are generated during the process. Cleaning processes are performed before and after each process to remove these particles and process by-products from the substrate.

A typical cleaning process involves treating the substrate with chemicals and rinse solutions, followed by drying. Recently, a supercritical drying process has been utilized in which the residual rinse solution on the substrate is replaced with an organic solvent, such as isopropyl alcohol (IPA), which has a low surface tension, by supplying the organic solvent on the substrate and the substrate is then supplied with supercritical drying gas (for example, carbon dioxide) to remove the residual organic solvent from the substrate. In the supercritical drying process, the drying fluid is supplied to a process chamber in which the inside is sealed, and the drying fluid is heated and pressurized. Accordingly, both the temperature and pressure of the drying fluid rise to a temperature equal to or higher than critical point, and the drying fluid changes phase to a supercritical state.

The temperature inside the supercritical drying chamber must be appropriately monitored to maintain the supercritical state of the drying fluid. In addition, the temperature for each treatment area must be uniform for uniform drying treatment in the substrate. In order to achieve this object, the temperature inside the chamber must be properly measured. However, since the inside of the chamber is maintained at high pressure and cleanliness must be maintained, it is difficult to measure the temperature by installing a temperature sensor inside the chamber, and thus there is a problem in that the temperature and temperature distribution inside the chamber are not properly measured.

### SUMMARY OF THE INVENTION

The present invention has been made in an effort to provide a substrate treating apparatus capable of appropriately measuring the temperature and temperature distribution of a treatment space for treating a substrate.

The present invention has also been made in an effort to provide a substrate treating apparatus capable of improving a temperature distribution of a treatment space for treating a substrate.

The present invention has also been made in an effort to provide a substrate treating apparatus capable of improving uniformity of drying treatment for a substrate.

The objectives of the present disclosure are not limited thereto and other objectives not stated herein may be clearly understood by those skilled in the art from the following description.

An exemplary embodiment of the present invention, an apparatus for treating a substrate, the apparatus comprising: a vessel having a treatment space; a support unit for supporting a substrate in the treatment space; a fluid supply unit for supplying a treatment fluid to the treatment space; a fluid exhaust unit for exhausting the treatment fluid from the treatment space; a heating unit installed in the vessel to heat the treatment space; and a temperature measurement unit installed in the vessel to measure the temperature of the treatment space, wherein the vessel includes: a housing providing the treatment space; and a cover unit for covering a part or an entirety of an inner wall of the housing exposed to the treatment space in the inner wall of the housing, and the temperature measurement unit may include a temperature sensor provided between the housing and the cover unit.

According to the exemplary embodiment of the present invention, the housing includes: an upper body; and a lower body that is combined with the upper body to form the treatment space, the cover unit includes an upper cover covering a surface of an inner wall of the upper body that is exposed to the treatment space, and the temperature measurement unit may be positioned between the upper body and the upper cover.

According to the exemplary embodiment of the present invention, the upper cover is detachably coupled to the upper body, and the temperature measurement unit may be detachably coupled to the upper cover.

According to the exemplary embodiment of the present invention, an insertion groove into which the temperature measurement unit is inserted may be formed on an upper surface of the upper cover.

According to the exemplary embodiment of the present invention, the temperature measurement unit further includes a plate-shaped plate, and the temperature sensor may be a first temperature sensor.

According to the exemplary embodiment of the present invention, an insertion groove into which the first temperature sensor is inserted may be formed on an upper surface of the plate.

According to the exemplary embodiment of the present invention, wherein the plate is provided in a ring shape, and an outer diameter of the plate may be provided larger than a diameter of the substrate supported by the support unit.

According to the exemplary embodiment of the present invention, the cover unit further includes a lower cover covering a surface of the inner wall of the lower body that is exposed to the treatment space, and the lower cover may be detachably coupled to the lower body.

According to the exemplary embodiment of the present invention, the support unit is fixedly coupled to the upper cover, and a distance between the substrate supported by the support unit and an interface between the upper cover and the upper body may be shorter than a distance between the substrate supported by the support unit and an interface between the lower cover and the lower body when the upper body and the lower body contact each other.

According to the exemplary embodiment of the present invention, the apparatus may further include a controller, wherein the heating unit includes: a heater inserted into an upper portion of the housing; and a second temperature sensor inserted into the upper body and measuring a temperature of the heater, and the controller may controls the heater by a value measured by the first temperature sensor and the second temperature sensor.

An exemplary embodiment of the present invention, an apparatus for treating a substrate, the apparatus comprising: a vessel having a treatment space; a support unit for supporting a substrate in the treatment space; a fluid supply unit for supplying a treatment fluid to the treatment space; a fluid exhaust unit for exhausting the treatment fluid from the treatment space; a heating unit installed in the vessel to heat the treatment space; and a measurement unit installed in the vessel to measure a state of the treatment space, wherein the vessel includes: a housing providing the treatment space; and a cover unit for covering a part or an entirety of an inner wall of the housing exposed to the treatment space in the inner wall of the housing, and the measurement unit may include a measurement sensor provided between the housing and the cover unit.

According to the exemplary embodiment of the present invention, the housing includes: an upper body; and a lower body that is combined with the upper body to form the treatment space, the cover unit includes an upper cover covering a surface of an inner wall of the upper body that is exposed to the treatment space, and the measurement unit may be positioned between the upper body and the upper cover.

According to the exemplary embodiment of the present invention, the upper cover may be detachably coupled to the upper body, and the measurement unit is detachably coupled to the upper cover.

According to the exemplary embodiment of the present invention, an insertion groove into which the measurement unit is inserted may be formed on an upper surface of the upper cover.

According to the exemplary embodiment of the present invention, the measurement unit further includes a ring-shaped plate on which the measurement sensor is installed, and an outer diameter of the plate may be provided larger than a diameter of the substrate supported by the support unit.

According to the exemplary embodiment of the present invention, the cover unit further includes a lower cover covering a surface of the inner wall of the lower body that is exposed to the treatment space, and the lower cover may be detachably coupled to the lower body.

According to the exemplary embodiment of the present invention, the measurement unit may be provided at a place having a shorter distance from the treatment space between a place between the upper body and the upper cover or a place between the lower body and the lower cover.

An exemplary embodiment of the present invention, an apparatus for treating a substrate, the apparatus comprising: a vessel having a treatment space; a support unit for supporting a substrate in the treatment space; a fluid supply unit for supplying a treatment fluid to the treatment space; a fluid exhaust unit for exhausting the treatment fluid from the treatment space; a heating unit installed in the vessel to heat the treatment space; and a temperature measurement unit installed in the vessel to measure the temperature of the treatment space, wherein the vessel includes: a housing providing the treatment space; and a cover unit for covering a part or an entirety of an inner wall of the housing exposed to the treatment space in the inner wall of the housing, and the housing includes: an upper body; and a lower body that is combined with the upper body to form the treatment space, the cover unit includes: an upper cover for covering an inner wall of the upper body that is exposed to the treatment space; and a lower cover for covering a surface of an inner wall of the lower body that is exposed to the treatment space, the upper cover is detachably coupled to the upper body, and the temperature measurement unit includes: a ring-shaped plate detachably coupled to the upper body; and a first temperature sensor installed on the plate, and the temperature measurement unit may be inserted into an insertion groove formed on an upper surface of the upper cover.

According to the exemplary embodiment of the present invention, the apparatus may further include a controller, wherein the heating unit includes: a heater inserted into the housing; and a second temperature sensor inserted into the upper body and measuring a temperature of the heater, and the controller may controls the heater by a value measured by the first temperature sensor and the second temperature sensor.

According to the exemplary embodiment of the present invention, an insertion groove into which the first temperature sensor is inserted is formed on an upper surface of the plate, the plate may be provided in a ring shape, and an outer diameter of the plate is provided larger than a diameter of the substrate supported by the support unit.

According to the exemplary embodiment of the present invention, it is possible to appropriately measure the temperature and temperature distribution of the treatment for treating the substrate.

According to the exemplary embodiment of the present invention, it is possible to improve the temperature distribution of the treatment space for treating the substrate.

According to the exemplary embodiment of the present invention, it is possible to improve uniformity of drying treatment for a substrate.

Effects of the present disclosure are not limited to those described above and effects not stated above will be clearly understood to those skilled in the art from the specification and the accompanying drawings.

### BRIEF DESCRIPTION OF THE DRAWINGS

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

FIG. 1 is a diagram schematically illustrating an exemplary embodiment of a substrate treating apparatus of the present invention.

FIG. 2 is a diagram schematically illustrating an exemplary embodiment of a liquid treating chamber of FIG. 1.

FIG. 3 is a diagram illustrating a phase change graph of carbon dioxide.

FIG. 4 is a diagram schematically illustrating an exemplary embodiment of a drying chamber of FIG. 1.

FIG. 5 is an enlarged view illustrating a portion related to a measurement unit in portion A of FIG. 4.

FIG. 6 is a diagram schematically illustrating an exemplary embodiment of the measurement unit of FIG. 4.

FIG. 7 is a diagram schematically illustrating another exemplary embodiment of the temperature measurement unit of FIG. 6.

FIG. 8 is a diagram schematically illustrating another exemplary embodiment of the temperature measurement unit of FIG. 5.

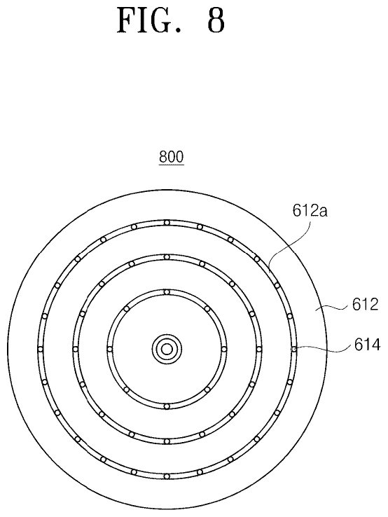

FIG. 9 is a diagram schematically illustrating another exemplary embodiment of the drying chamber of FIG. 4.

FIG. 10 is a view schematically illustrating another exemplary embodiment of the drying chamber of FIG. 4.

FIG. 11 is a view schematically illustrating another exemplary embodiment of the drying chamber of FIG. 4.

FIG. 12 is a view schematically illustrating another exemplary embodiment of the drying chamber of FIG. 4.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., +10%).

When the terms “about” or “substantially” are used in connection with a numerical value, it should be understood that the associated numerical value includes a manufacturing or operational tolerance (e.g., +10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, a wafer will be described as an example of an object to be treated. However, the technical spirit of the present invention may be applied to devices used for other types of substrate treatment, in addition to wafers.

Hereinafter, exemplary embodiments of the present invention will be described with reference to the accompanying drawings.

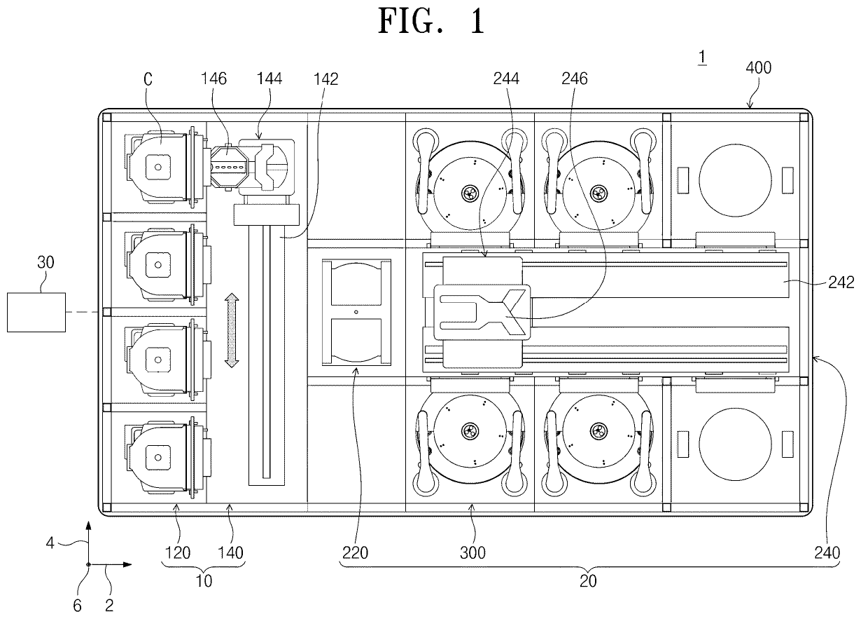

FIG. 1 is a diagram schematically illustrating an exemplary embodiment of a substrate treating apparatus of the present invention. Referring to FIG. 1, the substrate treating apparatus 1 includes an index module 10 and a treating module 20. According to the exemplary embodiment, the index module 10 and the treating module 20 are disposed in one direction. Hereinafter, a direction in which the index module 10 and the treating module 20 are arranged is defined as a first direction 2. When viewed from above, a direction perpendicular to the first direction 2 is defined as a second direction 4, and a direction perpendicular to a plane including both the first direction 2 and the second direction 4 is defined as a third direction 6.

The index module 10 transfers the substrate W from a cassette C in which the substrate W is accommodated to the treating module 20, which treats the substrate W. The index module 10 accommodates the substrate W that has been completely treated in the treating module 20 into the cassette C. A longitudinal direction of the index module 10 is provided in the second direction 4. The index module 10 includes a load port 110 and an index frame 140.

The cassette C, in which the substrate W is accommodated, is seated in the load port 120. The load port 120 is located at an opposite side of the treating module 20 based on the index module 140. A plurality of load ports 120 may be provided. A plurality of load ports 120 may be arranged in a line along the second direction 4. The number of load ports 120 may increase or decrease depending on process efficiency and footprint conditions of the treating module 20.

The cassette C is formed with a plurality of slots (not illustrated). The substrates W may be seated in the slots (not illustrated). The plurality of slots (not illustrated) may be spaced apart from each other in the third direction 6. The substrates W may be seated in the slots (not illustrated), respectively, and accommodated in the cassette C in a horizontally disposed state with respect to the ground.

As the cassette C, an airtight container, such as a Front Open Unified Pod (FOUP), may be used. The cassette C may be placed on the load port 120 by a transfer means (not illustrated), such as an overhead transfer, an overhead conveyor, or an automatic guided vehicle, or an operator.

An index rail 142 and an index robot 144 are provided inside the index frame 140. The index rail 142 is provided in the index frame 140 along the second direction 4 in its longitudinal direction. The index robot 144 may transfer the substrate W. The index robot 144 may transfer the substrate W between the index module 10 and the buffer unit 220, which will be described later.

The index robot 120 includes an index hand 146. On the index hand 146, the substrate W is seated. The index hand 146 may be provided on the index rail 142 to be movable along the second direction 4. Therefore, the index hand 146 is movable forwardly and backwardly along the index rail 142. Additionally, the index hand 146 may be provided to be rotatable about the third direction 6 as the axis. Additionally, the index hand 146 may be provided to be vertically movable along the third direction 6. A plurality of index hands 146 may be provided. The plurality of index hands 146 may be provided to be spaced apart from each other in the upward and downward direction. The plurality of index hands 146 may move forwardly, backwardly, and rotationally independently of each other.

The controller 30 may control the substrate treating apparatus 1. The controller 30 may include a process controller formed of a microprocessor (computer) that executes the control of the substrate treating apparatus 1, a user interface formed of a keyboard in which an operator performs a command input operation or the like in order to manage the substrate treating apparatus 1, a display for visualizing and displaying an operation situation of the substrate treating apparatus 1, and the like, and a storage unit storing a control program for executing the process executed in the substrate treating apparatus 1 under the control of the process controller or a program, that is, a treating recipe, for executing the process in each component according to various data and treating conditions. Further, the user interface and the storage unit may be connected to the process controller. The treatment recipe may be stored in a storage medium in the storage unit, and the storage medium may be a hard disk, and may also be a portable disk, such as a CD-ROM or a DVD, or a semiconductor memory, such as a flash memory.

Furthermore, the controller 30 may control the components provided in the drying chamber 500 described later to achieve the object of the present invention.

The treating module 20 includes a buffer unit 220, a transfer frame 240, a liquid treating chamber 300, and a drying chamber 500. The buffer unit 220 provides a buffer space where the substrate W loaded into the treating module 20 and the substrate W being unloaded from the treating module 20 temporarily stay. The transfer frame 240 provides a transfer space for transferring the substrate W between the buffer unit 220, the liquid treating chamber 300, and the drying chamber 500.

The liquid treating chamber 300 may perform a liquid treatment process by supplying liquid onto the substrate W to liquid-treat the substrate W. The drying chamber 500 may perform a drying treatment to remove any remaining liquid on the substrate W. The liquid treating chamber 300 and the drying chamber 400 may perform a cleaning process. The cleaning process may be performed sequentially in the liquid treating chamber 300 and the drying chamber 500. For example, the liquid treating chamber 300 may treat the substrate W by supplying chemicals, rinse solutions, and/or organic solvents onto the substrate W. For example, in the drying chamber 500, a drying treatment may be performed by using a supercritical fluid to remove any residual liquid on the substrate W.

The buffer unit 220 may be disposed between the index frame 140 and the transfer frame 240. The buffer unit 220 may be located at one end of the transfer frame 240. A slot (not illustrated) in which the substrate W is placed is provided inside the buffer unit 220. A plurality of slots (not illustrated) is provided. The plurality of slots (not illustrated) may be spaced apart from each other along the third direction 6. A front face and a rear face of the buffer unit 220 are opened. The front face may be the side facing the index frame 140, and the rear face may be the side facing the transfer frame 240. The index robot 144 may approach the buffer unit 220 through the front face, and a transfer robot 244 to be described later may approach the buffer unit 220 through the rear face.

A longitudinal direction of the transfer frame 240 may be provided along the first direction 2. The liquid treating chamber 300 and the drying chamber 500 may be disposed on opposite sides of the transfer frame 240. The liquid treating chamber 300 and the drying chamber 500 may be disposed on the side portion of the transfer frame 240. The transfer frame 240 and the liquid treating chamber 300 may be disposed along the second direction 4. Also, the transfer frame 240 and the drying chamber 500 may be disposed along the second direction 4.

In one example, the liquid treating chambers 300 are disposed on opposite sides of the transfer frame 240, and the drying chambers 500 are disposed on opposite sides of the transfer frame 240. The liquid treating chambers 300 may be disposed relatively closer to the buffer unit 220 than the drying chambers 500. At one side of the transfer chamber 240, the liquid treating chambers 300 may be provided in an arrangement of A×B (each of A and B is 1 or a natural larger than 1) in the first direction 2 and the third direction 6. Here, A is the number of liquid treating chambers 300 provided in a line along the first direction 2, and B is the number of liquid treating chambers 300 provided in a line along the third direction 6. For example, when four liquid treating chambers 300 are provided on one side of the transfer frame 240, the liquid treating chambers 300 may be arranged in a 2×2 arrangement. The number of liquid treating chambers 300 may be increased or decreased. As described above, the liquid treating chambers 300 may be provided only on one side of the transfer frame 240, and only the drying chambers 500 may be arranged on the other side opposite the one side. Further, the liquid treating chamber 300 and the drying chamber 500 may be provided in a single layer on one side and opposite sides of the transfer frame 240.

The transfer frame 240 includes a guide rail 242 and a transfer robot 244. The guide rail 242 and the transfer robot 244 are provided inside the transfer frame 240. A longitudinal direction of the guide rail 242 may be provided in the first direction 2. The transfer robot 244 may be provided on the guide rail 242 to be linearly movable along the first direction 2. The transfer robot 244 transfers the substrate W between the buffer unit 220, the liquid treating chamber 300, and the drying chamber 500.

The transfer robot 244 includes a transfer hand 246 on which the substrate W is placed. The transfer hand 246 may be provided on the guide rail 242 to be movable along the first direction 2. Accordingly, the transfer hand 246 is movable forwardly and backwardly along the guide rail 242. In addition, the transfer hand 246 may be provided to be rotatable about the third direction 6 and to be movable along the third direction 6. A plurality of transfer hands 246 may be provided. The plurality of transfer hands 246 may be provided to be spaced apart from each other in the vertical direction. The plurality of transfer hands 246 may move forwardly, backwardly, and rotationally independently of each other.

The liquid treating chamber 300 performs a liquid-treatment process on the substrate W. For example, the liquid treating chamber 300 may be a chamber that performs a cleaning process to remove impurities, such as process byproducts or particles, adhering to the substrate W. The liquid treating chamber 260 may have a different structure depending on the type of process treating the substrate W. Unlike this, each of the liquid treating chambers 300 may have the same structure.

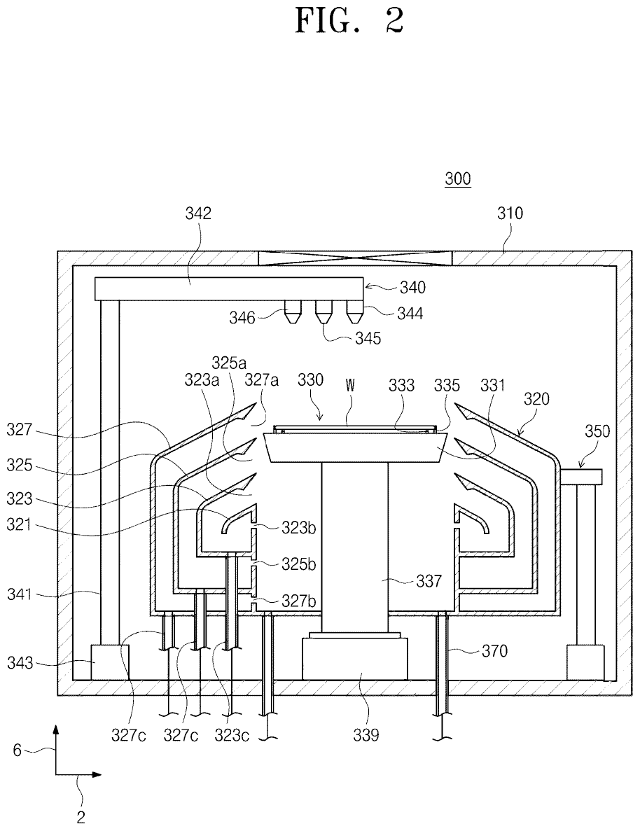

FIG. 2 is a diagram schematically illustrating an exemplary embodiment of the liquid treating chamber of FIG. 1. Referring to FIG. 2, the liquid treating chamber 300 includes a chamber 310, a treatment container 320, a support unit 330, and a liquid supply unit 340.

The chamber 310 has an interior space. The chamber 310 is provided in a generally cuboidal shape. An opening (not illustrated) is formed in one side of the chamber 310. The opening (not illustrated) functions as an entrance port through which the substrate W is loaded into and unloaded from of the interior space of the chamber 310 by the transfer robot 244. The treatment container 320, the support unit 330, and the liquid supply unit 340 are disposed in the interior space of the chamber 310.

The treatment container 320 has a treatment space with an opened upper portion. The treatment container 320 may be a bowl having a treatment space. The treatment container 320 may be provided to surround the treatment space. The treatment space of the treatment container 320 is provided as a space in which the support unit 330 described later supports and rotates the substrate W. Furthermore, the treatment space is provided as a space for the liquid supply unit 340, described later, to supply a liquid onto the substrate W to treat the substrate W.

According to the example, the treatment container 320 may have a guide wall 321 and a plurality of recovery containers 323, 325, and 327. Each of the recovery containers 323, 325, and 327 separately recovers different liquids from the liquids used to treat the substrate W. The recovery containers 323, 325, and 327 may each have a recovery space for recovering the liquid used to treat the substrate W.

The guide wall 321 and the recovery containers 323, 325, and 327 are provided in an annular ring shape surrounding the support unit 330. When a liquid is supplied onto the substrate W, the liquid that is scattered by the rotation of the substrate W may enter the recovery space through the inlets 323a, 325a, and 327a of the recovery containers 323, 325, and 327 described below. Different types of liquid may be introduced into of the recovery containers 323, 325, and 327, respectively.

The treatment container 320 includes a guide wall 321, a first recovery container 323, a second recovery container 325, and a third recovery container 327. The guide wall 321 is provided in an annular ring shape surrounding the support unit 330. The first recovery container 323 is provided in an annular ring shape surrounding the guide wall 321. The second recovery container 325 is provided in an annular ring shape surrounding the first recovery container 323. The third recovery container 327 is provided in an annular ring shape surrounding the second recovery container 325.

The space between the guide wall 321 and the first recovery container 323 functions as a first inlet 323a through which the liquid is introduced. A space between the first recovery container 323 and the second recovery container 325 functions as a second inlet 325a through which the liquid is introduced. A space between the second recovery container 325 and the third recovery container 327 functions as a third inlet 327a through which the liquid is introduced. The second inlet 325a may be located above the first inlet 323a, and the third inlet 327a may be located above the second inlet 325a. The liquid introduced into the first inlet 323a, the liquid introduced into the second inlet 325a, and the liquid introduced into the third inlet 327a may be different types of liquid.

The space between the bottom of the guide wall 321 and the first recovery container 323 functions as a first outlet 323b, through which impurities and airflow generated from the liquid are discharged. The space between the bottom of the first recovery container 323 and the second recovery container 325 functions as a second outlet 325b, through which impurities and airflow generated from the liquid are discharged. The space between the bottom of the second recovery container 325 and the third recovery container 327 functions as a third outlet 327b, through which impurities and airflow generated from the liquid are discharged. The impurities and airflow discharged from the first outlet 323b, the second outlet 325b, and the third outlet 327b are exhausted to the outside of the liquid treating chamber 300 via the exhaust unit 370 described later.

Recovery lines 323c, 325c, and 327c extending vertically downwardly are connected to the bottom surface of the recovery containers 323, 325, and 327, respectively. The recovery lines 323c, 325c, and 327c discharge the liquids that have been introduced through the recovery containers 323, 325, and 327, respectively. The discharged treatment liquid may be reused via an external liquid reclamation system (not illustrated).

The support unit 330 supports and rotates the substrate W in the treatment space. The supporting unit 330 may include a spin chuck 331, a supporting pin 333, a chuck pin 335, a rotating shaft 337, and a driver 339.

The spin chuck 331 has a top surface that is substantially circular when viewed from above. The top surface of the spin chuck 331 may have a diameter larger than the substrate W.

A plurality of support pins 333 is provided. The support pin 333 is disposed on the top surface of the spin chuck 331. The support pins 333 are spaced apart at regular intervals at the edge portion of the top surface of the spin chuck 331. The support pins 333 are formed to protrude upwardly from above surface of the spin chuck 331. The support pins 333 are arranged in combination with each other to form an overall annular ring shape. The support pin 333 supports an edge region of the rear surface of the substrate W so that the substrate W is spaced apart from above surface of the spin chuck 331 at a predetermined distance.

A plurality of chuck pins 335 is provided. The chuck pins 335 are disposed relatively farther away from the center region of the spin chuck 331 than the support pins 333. The chuck pins 335 protrude upwardly from above surface of the spin chuck 331. The chuck pin 335 supports a lateral region of the substrate W to prevent the substrate W from laterally deviating from its stationary position when the substrate W is rotated.

The rotation shaft 337 is coupled with the spin chuck 331. The rotation shaft 337 is coupled to the bottom surface of the spin chuck 331. The rotation shaft 337 may be provided with a longitudinal direction facing the third direction 6. The rotation shaft 337 is provided to be rotatable by receiving power from the driver 339. The rotation shaft 337 is rotated by the driver 339, and the spin chuck 331 is rotated by a medium of the rotation shaft 337. The driver 339 rotates the rotation shaft 337. The driver 339 is capable of varying the rotational speed of the rotation shaft 337. The driver 339 may be a motor that provides driving force. However, the driver is not limited thereto, and may be provided in various variations with any known device that provides driving force.

The liquid supply unit 340 supplies the liquid to the substrate W. The liquid supply unit 340 supplies a liquid to the substrate W supported by the support unit 330. The liquid supplied to the substrate W by the liquid supply unit 340 may be provided in a plurality of types. The liquid supply unit 340 may include a support rod 341, an arm 342, a driver 343, a first liquid supply nozzle 344, and a second liquid supply nozzle 345.

A support rod 341 is located in the interior space of the chamber 310. The support rod 341 may be located on one side of the treatment container 320 in the interior space. The support rod 2641 may have a rod shape in which a longitudinal direction faces the third direction 6. The support rod 341 is provided to be rotatable by the driver 343 to be described later.

The arm 342 is coupled to an upper end of the support rod 341. The arm 342 extends vertically from the longitudinal direction of the support rod 341. The arm 342 may be provided in the third direction 6 along its length. The first liquid supply nozzle 344, the second liquid supply nozzle 345, and the third liquid supply nozzle 346 to be described later may be fixedly coupled to the end of the arm 342.

The arm 342 may be provided to be movable forwardly and backwardly along its longitudinal direction. The arm 342 may be swing moveable via the support rod 341 by the driver 343 that rotates the support rod 341. By the rotation of the arm 342, the first liquid supply nozzle 344, the second liquid supply nozzle 345, and the third liquid supply nozzle 346 may also be swing-moved to be moved between a process position and a standby position.

The process position may be a position where any one of the first liquid supply nozzle 344, the second liquid supply nozzle 345, and the third liquid supply nozzle 346 faces the substrate W supported by the support unit 330. According to the example, the process position may be a position where the center of any one of the first liquid supply nozzle 344, the second liquid supply nozzle 345, and the center of the substrate W supported by the support unit 330 faces each other. The standby position may be a position where the first liquid supply nozzle 344, the second liquid supply nozzle 345, and the third liquid supply nozzle 346 are all out of the process position.

The driver 343 is coupled with the support rod 341. The driver 343 may be disposed on the bottom surface of the chamber 310. The driver 343 provides driving force for rotating the support rod 341. The driver 343 may be provided as a known motor that provides driving force.

The first liquid supply nozzle 344 supplies the first liquid onto the substrate W. The first liquid supply nozzle 344 may supply a first liquid onto the substrate W supported by the support unit 330. The second liquid supply nozzle 345 supplies a second liquid onto the substrate W. The second liquid supply nozzle 345 supplies the second liquid onto the substrate W supported by the support unit 330. The third liquid supply nozzle 346 supplies a third liquid onto the substrate W. The third liquid supply nozzle 346 supplies the third liquid onto the substrate W supported by the support unit 330.

According to the exemplary embodiment, the first solution, the second solution, and the third solution may be any one of chemical, rinse solution, and organic solvent. For example, the chemical may include diluted sulfuric acid (H₂SO₄), phosphoric acid (P₂O₅), hydrofluoric acid (HF), and ammonium hydroxide (NH₄OH). For example, the rinse solution may include water or deionized water (DIW). For example, the organic solvent may include an alcohol, such as isopropyl alcohol (IPA). According to the exemplary embodiment, the first liquid may be chemical. Also, the second liquid may be a rinse solution. Further, the third liquid may be an organic solvent.

The exemplary embodiment of the present invention has been described based on the case where in the liquid supply unit 340, the first liquid supply nozzle 344, the second liquid supply nozzle 345, and the third liquid supply nozzle 346 are all coupled to the arm 342 as an example, but the present invention is not limited thereto. For example, the first liquid supply nozzle 344, the second liquid supply nozzle 345, and the third liquid supply nozzle 346 may each independently have an arm, a support rod, and a driver, and may independently move between a process position and a standby position by swing movement and forward/rearward movement.

The lifting unit 350 is disposed in the interior space of the chamber 310. The lifting unit 350 adjusts the relative height between the treatment container 320 and the support unit 330. The lifting unit 350 may move the treatment container 320 in a straight line in the third direction 6. Accordingly, since the height of the recovery containers 323, 325, and 327 for recovering the liquid is changed according to the type of the liquid supplied to the substrate W, the liquids may be separated and recovered. Unlike the above, the treatment container 320 is fixedly installed, and the lifting unit 350 may change the relative height between the support unit 330 and the treatment container 320 by moving the support unit 330 in the vertical direction.

The exhaust unit 370 exhausts impurities generated in the treatment space. Impurities generated during liquid treatment of the substrate W are exhausted by a pressure reducing unit (not illustrated) provided in the exhaust unit 370. The exhaust unit 370 may be coupled to the bottom surface of the treatment container 320. In one example, the exhaust unit 370 may be disposed in the space between the rotation shaft 337 and the inner wall of the treatment container 320.

The drying chamber 500 may be a process chamber that is sealed from the outside environment. The drying chamber 500 removes the liquid remaining on the substrate W using a drying fluid. According to an example, the drying chamber 500 removes a liquid (e.g., an organic solvent) remaining on the substrate W by using a supercritical drying fluid (hereinafter referred to as a “supercritical fluid”). In the drying chamber 500, a supercritical process is performed by using the properties of the supercritical fluid. Representative examples thereof include a supercritical drying process and a supercritical etching process. Hereinafter, the supercritical process will be described based on the supercritical drying process. However, this is for ease of understanding only, and the drying chamber 500 may perform other supercritical processes other than the supercritical drying process. In the exemplary embodiment, the supercritical fluid may be supercritical carbon dioxide (scCO₂).

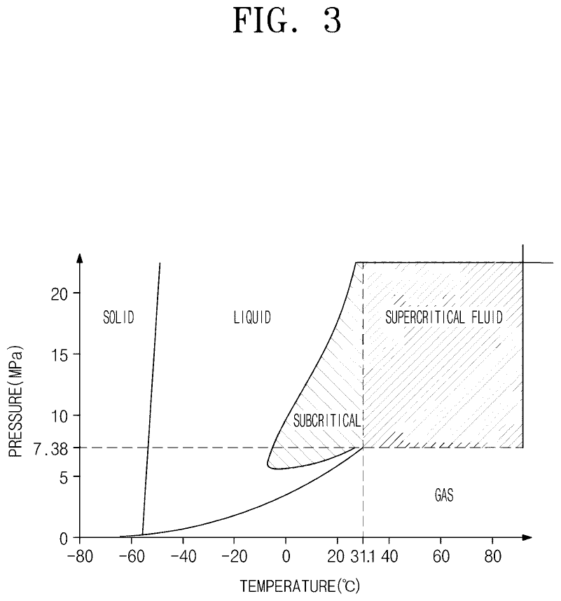

FIG. 3 is a diagram illustrating a phase change graph of carbon dioxide. Referring to FIG. 3, carbon dioxide has a critical temperature of 31.1É and a relatively low critical pressure of 7.38 MPa, so that carbon dioxide may be easily made to a supercritical state, and it is easy to control phase change of carbon dioxide by adjusting temperature and pressure, and carbon dioxide is low priced. In addition, carbon dioxide is non-toxic and harmless to the human body, and has characteristics of non-combustibility and inertness. Compared with water or other organic solvents, the diffusion coefficient of supercritical carbon dioxide is about 10 to 100 times higher, so that penetration of the supercritical carbon dioxide is fast, and the supercritical carbon dioxide is quickly replaced with the organic solvents. In addition, since supercritical carbon dioxide has almost no surface tension, the supercritical carbon dioxide has advantageous properties to be used for drying the substrate W including a fine circuit pattern. In addition, by-product of various chemical reactions of the supercritical carbon dioxide may be recycled, and at the same time, the supercritical carbon dioxide may be converted into a gas after being used in the supercritical drying process and the organic solvent may be separated and reused, so that there is less burdensome in terms of environmental pollution.

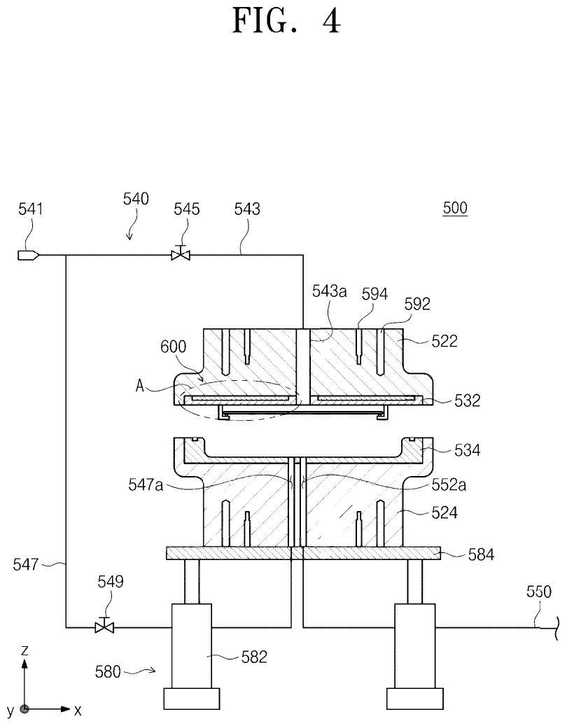

FIG. 4 is a diagram schematically illustrating an exemplary embodiment of the drying chamber of FIG. 1. In the drying chamber 500 according to the exemplary embodiment of the present invention, a treatment liquid remaining on the substrate W may be removed using a supercritical fluid. For example, the drying chamber 500 may perform a drying process to remove the organic solvent remaining on the substrate W by using supercritical carbon dioxide (CO2).

Referring to FIG. 4, the drying chamber 500 may include a vessel 510, a fluid supply unit 540, a fluid exhaust unit 550, a support unit 570, a lifting unit 580, a heating unit 589, and a temperature measurement unit 600.

The vessel 510 includes a housing 520 and a cover unit 530. The housing 520 provides a treatment space 520a. The housing 520 includes an upper body 522 and a lower body 524. The upper body 522 and the lower body 524 are arranged in the vertical direction. The upper body 522 is located above the lower body 524. One of the upper body 522 and the lower body 524 may be provided to be moved up and down by the lifting unit 580 to be described later. Accordingly, the treatment space 520a may be opened or closed. Also, a plurality of insertion holes 520b may be formed in the upper body 522 and the lower body 524. A plurality of insertion holes 520b may be provided. The insertion holes 520b may be provided in the number corresponding to the number of heating units 590 to be described later. Two of a plurality of insertion holes 520b may be provided to form a pair. Each pair may be provided to be spaced apart from each other. A heater 592 and a second temperature sensor 594 may be inserted into a pair of insertion holes 520b, respectively.

The cover unit 530 includes an upper cover 532 and a lower cover 534. The upper cover 532 and the lower cover 534 are vertically arranged. The upper cover 532 is positioned above the lower cover 534. A groove may be formed at a point where the upper cover 532 and the lower cover 534 contact each other, and an O-ring 526 that is a sealing member may be inserted into the groove. Accordingly, airtightness of the treatment space 520a may be improved. Airtightness of the treatment space 520a may be further improved by a clamping unit which is not illustrated. The clamping unit is provided to clamp the upper body 522 and the lower body 524.

The upper cover 532 is provided to cover a surface of an inner wall of the upper body 522 that is exposed to the treatment space 520a. The upper cover 532 may be detachably coupled to the upper body 522. The upper body 522 and the upper cover 532 may be formed of the same material. An insertion groove 532a may be formed on the upper surface of the upper cover 532. The insertion groove 532a may be formed to have a shape corresponding to that of the temperature measurement unit 600 to be described later. The depth of the insertion groove 532a may be provided with a length corresponding to the height of the temperature measurement unit 600. Accordingly, the temperature measurement unit 600 may be inserted into the insertion groove 532a. An anti-friction film 536 capable of reducing friction with the temperature measurement unit 600 may be formed in the insertion groove 532a. Accordingly, generation of particles may be minimized when replacing the temperature measurement units 600, 700 and 800. The lower cover 534 is provided to cover a surface of the inner wall of the lower body 524 that is exposed to the treatment space 520a. The lower cover 534 may be detachably coupled to the lower body 524.

The fluid supply unit 540 may supply the treatment fluid to the treatment space 520a. The treatment fluid may be a drying fluid. According to the example, the drying fluid supplied by the fluid supply unit 540 may include carbon dioxide (CO2). The fluid supply unit 540 may include a fluid supply source 541, a first supply line 543, a first supply valve 545, a second supply line 547, and a second supply valve 549. The fluid supply source 541 may store and/or supply a drying fluid supplied to the treatment space 520a. The fluid supply source 541 may supply a drying fluid to the first supply line 543 and/or the second supply line 547. For example, the first supply valve 545 may be installed in the first supply line 543. Furthermore, the first supply line 543 may be connected to a first supply channel 543a formed on the upper body 522 and the upper cover 532. The first supply line 543 may be provided to be separable upstream from a point connected to the first supply channel 543a. Accordingly, when the upper body 522 is separated from the upper cover 532, the upper body 522 may be easily separated. Furthermore, the second supply valve 549 may be installed in the second supply line 547. Furthermore, the second supply line 547 may be connected to a second supply channel 547a formed on the lower body 524 and the lower cover 534. The first supply valve 545 and the second supply valve 549 may be on/off valves. The drying fluid may selectively flow through the first supply line 543 or the second supply line 547 according to on/off operations of the first supply valve 545 and the second supply valve 549.

In the above-described example, the present invention has been described based on the case where the first supply line 543 and the second supply line 547 are connected to one fluid supply source 541 an example, but the present invention is not limited thereto. For example, a plurality of fluid supply sources 541 may be provided, the first supply line 543 may be connected to any one of the plurality of fluid supply sources 541, and the second supply line 547 may also be connected to another one of the fluid supply sources 541.

Furthermore, the first supply line 543 may be an upper supply line for supplying a drying fluid from an upper portion of the treatment space 520a. For example, the first supply line 543 may supply a drying fluid to the treatment space 520a in a direction from top to bottom. Furthermore, the second supply line 547 may be a lower supply line for supplying a drying fluid from a lower portion of the treatment space 520a. For example, the second supply line 547 may supply a drying fluid to the treatment space 520a in a direction from bottom to top.

The fluid exhaust unit 550 may exhaust the fluid for drying from the treatment space 520a. The fluid exhaust unit 550 may include a fluid exhaust line 552 and a pressure reducing member (not illustrated). One end of the fluid exhaust line 552 may be connected to the exhaust channel 552 formed in the lower body 524 and the lower cover 534, and the other end thereof may be connected to the pressure reducing member. The pressure reducing member decompresses the treatment space. According to the exemplary embodiment, the pressure reducing member may be a pump. However, the present invention is not limited thereto, and the pressure reducing member may be variously modified into a known device capable of providing decompression to the treatment space 520a.

The blocking unit 560 prevents the supercritical fluid supplied from the second supply channel 547a from being directly discharged toward the substrate W, thereby preventing the lower surface of the substrate W from being damaged. The blocking unit 560 includes a blocking plate 561 and a fixing rod 562.

The support unit 570 supports the substrate W in the treatment space 520a. The supporting unit 570 may be installed in the upper body 522. The supporting unit 570 includes a fixing rod 572 and a holder 574. The supporting unit 570 may be symmetrically disposed on opposite sides with respect to the substrate W. The fixing rods 572 may be provided in a bar shape extending downward from a bottom surface of the upper body 522. A plurality of fixing rods 572 is provided. The holder 574 has an arc shape. The holder 574 extends in a vertical direction from a lower end of the fixing rod 572. The holder 574 extends in an inner direction of the fixing rod 572.

The lifting unit 580 may include a lifting driver 582 and a lifting plate 584. The lifting drivers 582 may be provided in plurality and may be coupled to the lifting plate 584. The lifting plate 584 may be coupled to the lower body 524. When the lifting driver 582 lifts the lifting plate 582, the lower body 524 may be lifted along with the lifting plate 584. However, the present invention is not limited thereto, and the lower body 524 is fixed, and the lifting unit 580 may be configured to lift the upper body 522.

The heating unit 590 includes a heater 592 and a second temperature sensor 594. The heater 592 may heat the treatment space 520a and the fluid for drying. The heater 592 may be inserted into the insertion hole 520b. According to the example, the heater 592 may be a cartridge heater. The second temperature sensor 594 measures a temperature of the heater 592. The second temperature sensor 594 may be inserted into the insertion hole 520b. Accordingly, the second temperature sensor 594 may be provided adjacent to the heater 592. According to the example, the second temperature sensor 594 may be a thermocouple. The heater 592 emits thermal energy, and the thermal energy is conducted through the upper body 522. Thermal energy is conducted to the second temperature sensor 594, and the second temperature sensor 594 indirectly measures a temperature of the heater 592. The controller 30 may infer whether the heater 592 operates normally and the temperature of the treatment space 520a from the temperature measured by the second temperature sensor 594.

The heater 592 and the second temperature sensor 594 may be provided in a pair, and a plurality of heaters 592 and second temperature sensors 594 may be provided. According to the example, four heaters 592 and four second temperature sensors 594 may be provided at the upper body 522 and the lower body 524. In this case, the heaters 592 and the second temperature sensors 594 may be provided at 90-degree intervals when viewed from above. Further, the heater 592 and the second temperature sensor 594 provided to the upper body 522 and the lower body 524 may be provided so as not to overlap each other when viewed from above. According to the example, the heater 592 and the second temperature sensor 594 provided to the upper body 522 may be provided at positions rotated by 45 degrees with respect to the heater 592 and the second temperature sensor 594 provided to the lower body 524. In FIG. 4, the heating unit 590 is illustrated in the upper body 522 and the lower body 524 to show that the treatment space 520a is heated at upper and lower portions of the treatment space 520a.

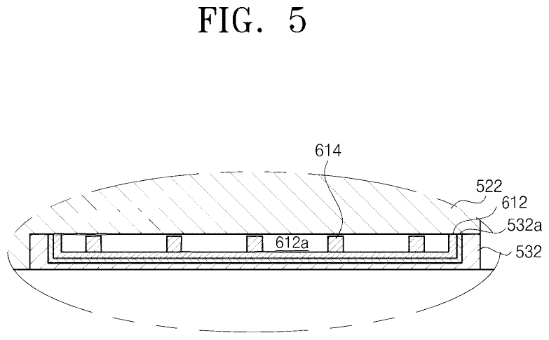

The temperature measurement unit 600 measures a temperature of the treatment space 520a. FIG. 5 is a diagram schematically illustrating an exemplary embodiment of the temperature measurement unit of FIG. 4. Referring to FIG. 5, the temperature measurement unit 600 includes a plate 612 and a first temperature sensor 614.

The plate 612 may be provided in a ring shape. A groove 612a may be formed on a top surface of the plate 612. A plurality of grooves 612a may be provided. The groove 612a may be provided in a linear shape and/or a ring shape. According to the example, the groove 612a may include a plurality of concentric circles formed with respect to the center of the plate 612 and a plurality of linear shapes having a shape radiating in a radial direction. The plate 612 may be provided in the groove 532a formed in the upper cover 532. The plate 612 may be detachably provided in the groove 532a. The plate 612 may be coupled to the upper body 522 by a coupling part (not illustrated). According to the example, the plate 612 may be coupled to each other by a bolt. However, the present invention is not limited thereto, and may be variously modified and provided in a known configuration providing a coupling force. Accordingly, the temperature measurement unit 600 may be positioned between the upper body 522 and the upper cover 532.

The first temperature sensor 614 may be installed in the groove 612a. A plurality of first temperature sensors 614 may be provided, and may be installed along the shape of the groove 612a. Accordingly, the temperature and temperature distribution of the treatment space 520a may be measured. Further, when the first temperature sensor 614 is treating the substrate W, the first temperature sensor 614 may measure the temperature in real time. Here, the thermal energy of the treatment space 520a is conducted to the first temperature sensor 614 through the upper cover 532, and the first temperature sensor 614 determines the temperature of the treatment space 520a according to the conducted thermal energy. The first temperature sensor 614 may be provided in a form in which a thermistor is installed on a Flexible Printed Circuit Board (FPCB), for example. Alternatively, the first temperature sensor 614 may be provided as an exposed thermocouple. However, the present invention is not limited thereto, and may be provided by various modifications to a known sensor capable of measuring temperature with a form that may be inserted into the groove 612a.

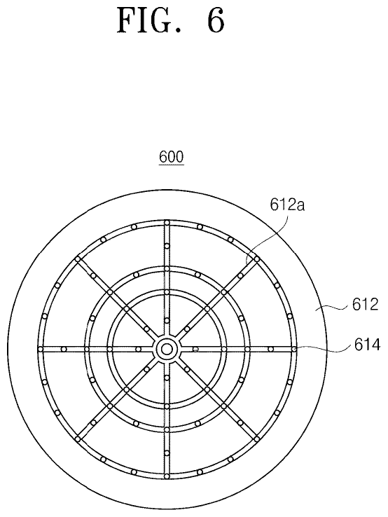

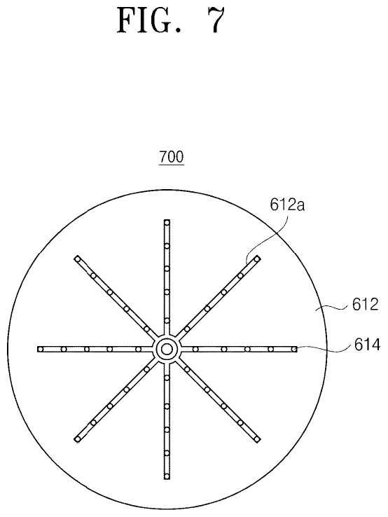

FIGS. 6 and 7 are diagrams schematically illustrating other exemplary embodiments of the measurement unit of FIG. 4. Referring to FIGS. 6 and 7, the temperature measurement unit may be 600 a temperature measurement unit 700, or a temperature measurement unit 800 according to the shape of the groove 612a formed in the plate 612. The upper body 522 and the upper cover 532 are detachably coupled to each other, and the upper cover 532 and the temperature measurement units 600, 700, and 800 are detachably coupled. Accordingly, the temperature measurement units 600, 700, and 800 may be selectively installed to appropriately measure a temperature distribution of the treatment space 520a according to a process type and conditions.

A plurality of first temperature sensors 614 measures the treatment space 520a for each area. The first temperature sensor 614 may measure the temperature of the treatment space 520a in real time during the process. The controller 30 determines whether the temperature of the treatment space 520a and the temperature distribution are abnormal while the process is in progress, based on the measured temperature. Thereafter, the controller 30 controls the heater 592 according to whether the temperature of the treatment space 520a or the temperature distribution is abnormal.

According to the prior art, the temperature of the treatment space 520a and the temperature of the treatment fluid cannot be measured by installing a temperature sensor in the treatment space 520a due to the pressure of the treatment space 520a and the need to maintain cleanliness, and the temperature of the treatment space 520a and the temperature of the treatment fluid are only inferred indirectly by measuring the temperature of the heater 592 measured by the second temperature sensor 594.

However, according to the exemplary embodiment of the present invention, the vessel 510 includes a housing 520 and a cover unit 530, and a first temperature sensor 614 is provided therebetween, so that the first temperature sensor 614 may be installed adjacent to the treatment space 520a, and thus the temperature of the treatment space 520a may be more accurately measured. Further, the temperature uniformity of the treatment space 520a may be improved by controlling the heater 592 through the measured temperature. Accordingly, uniformity of drying treatment on the substrate W may be improved.

In the above example, the present invention has been described based on the case where the temperature measurement unit 600 measures a temperature of the treatment space 520a as an example. However, the present invention is not limited thereto, and a measurement unit in which a measurement sensor for measuring a state of the treatment space, in addition to the temperature of the treatment space, may be installed may be provided.

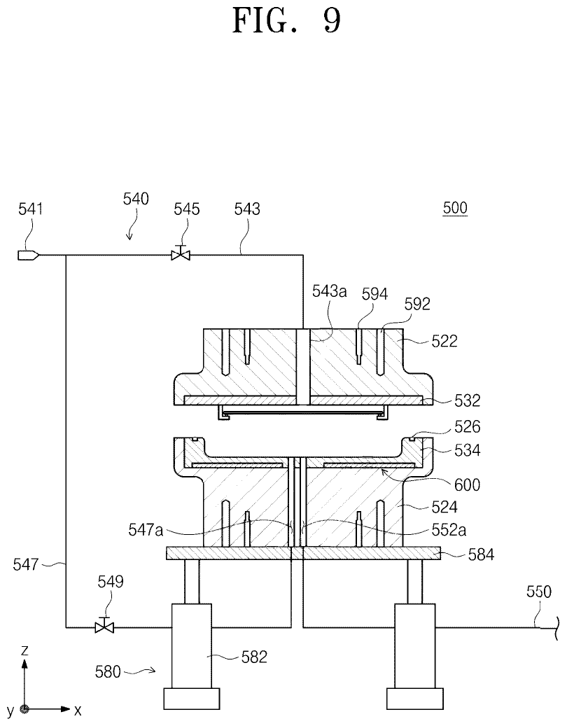

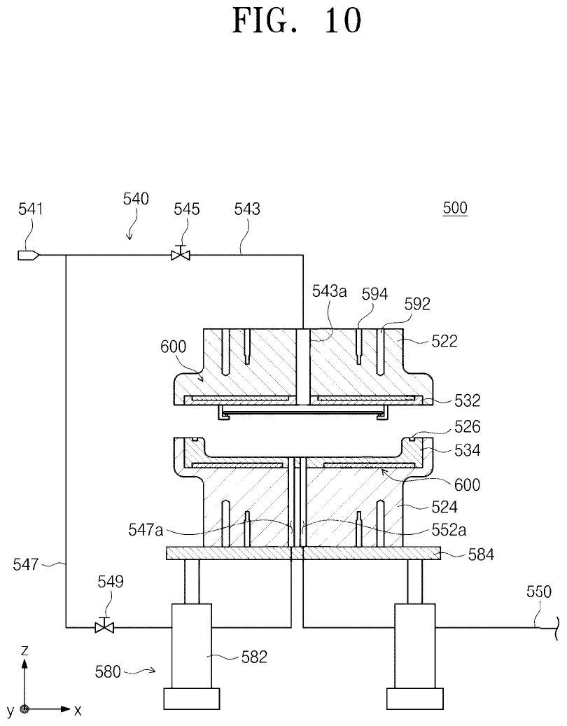

Furthermore, in the above example, the present invention has been described based on the case where the temperature measurement unit 600 is provided between the upper body 522 and the upper cover 532 as an example. However, the present invention is not limited thereto, and may be provided between the lower body 524 and the lower cover 534 as illustrated in FIG. 9. Alternatively, as illustrated in FIG. 10, the temperature measurement unit 600 may be provided between the upper body 522 and the upper cover 532 and between the lower body 524 and the lower cover 534.

In addition, in the above-described example, the present invention has been described based on the case where the lower body 524 and the lower cover 534 are detachably provided as an example. However, the present invention is not limited thereto, and the lower body 524 and the lower cover 534 may be provided integrally.

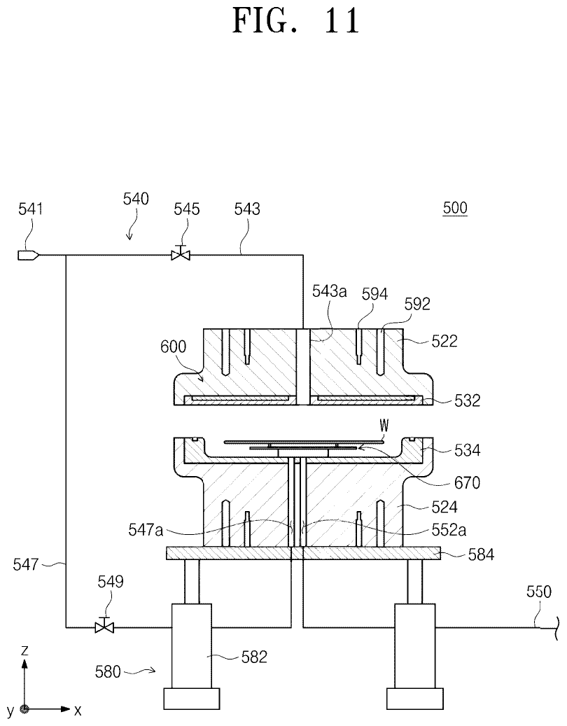

Also, in the above-described example, the present invention has been described based on the case where the support unit 570 is installed on the upper cover 532 as an example. However, the present invention is not limited thereto, and the support unit 670 may also be installed on the lower cover 534 as illustrated in FIG. 11.

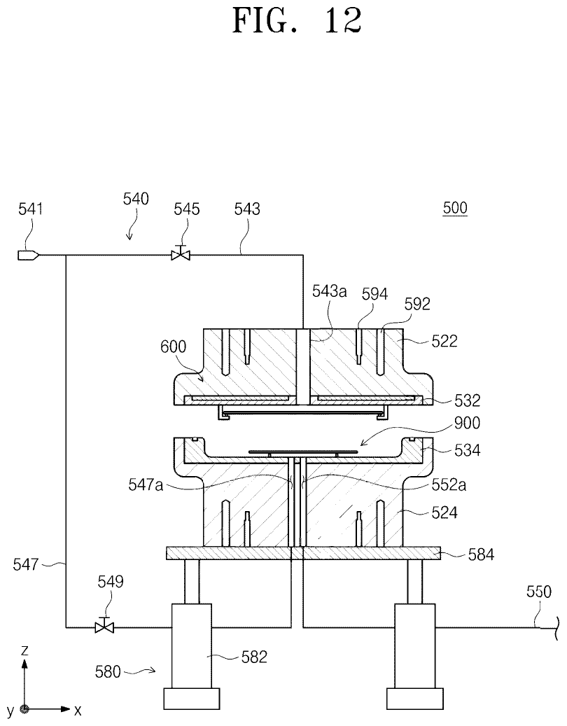

In addition, in the above-described example, the present invention has been described based on the case where the treatment fluid supplied to the second supply channel 574a is directly supplied to the lower surface of the substrate W. However, the present invention is not limited thereto, and a blocking unit, which is a circular plate, may be provided on the path of the treatment fluid supplied from the treatment space 520a to the second supply channel 574a as illustrated in FIG. 12 to prevent the treatment fluid from being directly supplied to the lower surface of the substrate W.

The specification described above provides examples of the present disclosure. Further, the description provides exemplary embodiments of the present disclosure and the present disclosure may be used in other various combinations, changes, and environments. That is, the present disclosure may be changed or modified within the scope of the present disclosure described herein, within a range equivalent to the description, and/or within the knowledge or technology in the related art. The embodiment shows an optimum state for achieving the spirit of the present disclosure and may be changed in various ways for the detailed application fields and use of the present disclosure. Therefore, the detailed description of the present disclosure is not intended to limit the present disclosure in the embodiment. Further, the claims should be construed as including other embodiments.

What is claimed is:

1. An apparatus for treating a substrate, the apparatus comprising:
a vessel having a treatment space;
a support unit for supporting a substrate in the treatment space;
a fluid supply unit for supplying a treatment fluid to the treatment space;
a fluid exhaust unit for exhausting the treatment fluid from the treatment space;
a heating unit installed in the vessel to heat the treatment space; and
a temperature measurement unit installed in the vessel to measure the temperature of the treatment space,
wherein the vessel includes:
a housing providing the treatment space; and
a cover unit for covering a part or an entirety of an inner wall of the housing exposed to the treatment space in the inner wall of the housing, and
the temperature measurement unit includes a temperature sensor provided between the housing and the cover unit.

2. The apparatus of claim 1, wherein the housing includes:
an upper body; and
a lower body that is combined with the upper body to form the treatment space,
the cover unit includes an upper cover covering a surface of an inner wall of the upper body that is exposed to the treatment space, and
the temperature measurement unit is positioned between the upper body and the upper

3. The apparatus of claim 2, wherein the upper cover is detachably coupled to the upper body, and
the temperature measurement unit is detachably coupled to the upper cover.

4. The apparatus of claim 3, wherein an insertion groove into which the temperature measurement unit is inserted is formed on an upper surface of the upper cover.

5. The apparatus of claim 1, wherein the temperature measurement unit further includes a plate-shaped plate, and
the temperature sensor is a first temperature sensor.

6. The apparatus of claim 5, wherein an insertion groove into which the first temperature sensor is inserted is formed on an upper surface of the plate.

7. The apparatus of claim 5, wherein the plate is provided in a ring shape, and
an outer diameter of the plate is provided larger than a diameter of the substrate supported by the support unit.

8. The apparatus of claim 2, wherein the cover unit further includes a lower cover covering a surface of the inner wall of the lower body that is exposed to the treatment space, and
the lower cover is detachably coupled to the lower body.

9. The apparatus of claim 8, wherein the support unit is fixedly coupled to the upper cover, and
a distance between the substrate supported by the support unit and an interface between the upper cover and the upper body is shorter than a distance between the substrate supported by the support unit and an interface between the lower cover and the lower body when the upper body and the lower body contact each other.

10. The apparatus of claim 6, further comprising:
a controller,
wherein the heating unit includes:
a heater inserted into an upper portion of the housing; and
a second temperature sensor inserted into the upper body and measuring a temperature of the heater, and
the controller controls the heater by a value measured by the first temperature sensor and the second temperature sensor.

11. An apparatus for treating a substrate, the apparatus comprising:
a vessel having a treatment space;
a support unit for supporting a substrate in the treatment space;
a fluid supply unit for supplying a treatment fluid to the treatment space;
a fluid exhaust unit for exhausting the treatment fluid from the treatment space;
a heating unit installed in the vessel to heat the treatment space; and
a measurement unit installed in the vessel to measure a state of the treatment space,
wherein the vessel includes:
a housing providing the treatment space; and
a cover unit for covering a part or an entirety of an inner wall of the housing exposed to the treatment space in the inner wall of the housing, and
the measurement unit includes a measurement sensor provided between the housing and the cover unit.

12. The apparatus of claim 11, wherein the housing includes:
an upper body; and
a lower body that is combined with the upper body to form the treatment space,
the cover unit includes an upper cover covering a surface of an inner wall of the upper body that is exposed to the treatment space, and
the measurement unit is positioned between the upper body and the upper cover.

13. The apparatus of claim 12, wherein the upper cover is detachably coupled to the upper body, and
the measurement unit is detachably coupled to the upper cover.

14. The apparatus of claim 13, wherein an insertion groove into which the measurement unit is inserted is formed on an upper surface of the upper cover.

15. The apparatus of claim 11, wherein the measurement unit further includes a ring-shaped plate on which the measurement sensor is installed, and
an outer diameter of the plate is provided larger than a diameter of the substrate supported by the support unit.

16. The apparatus of claim 12, wherein the cover unit further includes a lower cover covering a surface of the inner wall of the lower body that is exposed to the treatment space, and
the lower cover is detachably coupled to the lower body.

17. The apparatus of claim 16, wherein the measurement unit is provided at a place having a shorter distance from the treatment space between a place between the upper body and the upper cover or a place between the lower body and the lower cover.

18. An apparatus for treating a substrate, the apparatus comprising:
a vessel having a treatment space;
a support unit for supporting a substrate in the treatment space;
a fluid supply unit for supplying a treatment fluid to the treatment space;
a fluid exhaust unit for exhausting the treatment fluid from the treatment space;
a heating unit installed in the vessel to heat the treatment space; and
a temperature measurement unit installed in the vessel to measure the temperature of the treatment space,
wherein the vessel includes:
a housing providing the treatment space; and
a cover unit for covering a part or an entirety of an inner wall of the housing exposed to the treatment space in the inner wall of the housing, and
the housing includes:
an upper body; and
a lower body that is combined with the upper body to form the treatment space,
the cover unit includes:
an upper cover for covering an inner wall of the upper body that is exposed to the treatment space; and
a lower cover for covering a surface of an inner wall of the lower body that is exposed to the treatment space,
the upper cover is detachably coupled to the upper body, and
the temperature measurement unit includes:
a ring-shaped plate detachably coupled to the upper body; and
a first temperature sensor installed on the plate, and
the temperature measurement unit is inserted into an insertion groove formed on an upper surface of the upper cover.

19. The apparatus of claim 18, further comprising:
a controller,
wherein the heating unit includes:
a heater inserted into the housing; and
a second temperature sensor inserted into the upper body and measuring a temperature of the heater, and
the controller controls the heater by a value measured by the first temperature sensor and the second temperature sensor.

20. The apparatus of claim 18, wherein an insertion groove into which the first temperature sensor is inserted is formed on an upper surface of the plate,
the plate is provided in a ring shape, and
an outer diameter of the plate is provided larger than a diameter of the substrate supported by the support unit.
